(19) United States
(12) Patent Application Publication
(10) Pub. No.: US 2025/0183852 A1
(43) Pub. Date: Jun. 5, 2025

(54) AMPLIFIER CIRCUIT

(71) Applicant: SUMITOMO ELECTRIC INDUSTRIES, LTD., Osaka (JP)

(72) Inventor: Hirotaka ASAMI, Osaka-shi (JP)

(73) Assignee: SUMITOMO ELECTRIC INDUSTRIES, LTD., Osaka (JP)

(21) Appl. No.: 18/962,792

(22) Filed: Nov. 27, 2024

(30) Foreign Application Priority Data
Dec. 1, 2023 (JP) 2023-204031

(51) Int. Cl. H03F 1/02; H03F 3/21

(52) U.S. Cl. CPC H03F 1/0288; H03F 3/211

(57) ABSTRACT

An amplifier circuit includes a divider that divides an input signal into a first signal and a second signal, a first amplifier that hags a first node receiving the first signal, amplifies the first signal received at the first node, and outputs an amplified first signal as a third signal, a second amplifier that has a second node receiving the second signal, amplifies the second signal received at the second node, and outputs an amplified second signal as a fourth signal, a path that connects the first node to the second node in a direct-current manner via the divider, and a combiner that combines the third signal and the fourth signal. The path is provided with a third node at one location to supply a bias voltage to the first amplifier and the second amplifier.

### CROSS REFERENCE TO RELATED APPLICATIONS

This application claims priority based on Japanese Patent Application No. 2023-204031 filed on Dec. 1, 2023, and the entire contents of the Japanese patent application are incorporated herein by reference.

### TECHNICAL FIELD

The present invention relates to an amplifier circuit.

### BACKGROUND

A balanced amplifier is known as an amplifier circuit for amplifying a high frequency signal such as a microwave (see patent literature: Japanese National Publication of International Patent Application No. 2022-506367).

### SUMMARY

An amplifier circuit according to an embodiment of the present disclosure includes a divider that divides an input signal into a first signal and a second signal, a first amplifier that has a first node receiving the first signal, amplifies the first signal received at the first node, and outputs an amplified first signal as a third signal, a second amplifier that has a second node receiving the second signal, amplifies the second signal received at the second node, and outputs an amplified second signal as a fourth signal, a path that connects the first node to the second node in a direct-current manner via the divider, and a combiner that combines the third signal and the fourth signal. The path is provided with a third node at one location to supply a bias voltage to the first amplifier and the second amplifier.

An amplifier circuit according to an embodiment of the present disclosure includes a divider that divides an input signal into a first signal and a second signal, a first amplifier that has a first node receiving the first signal, amplifies the first signal received at the first node, and outputs an amplified first signal as a third signal, a second amplifier that has a second node receiving the second signal, amplifies the second signal received at the second node and outputs an amplified second signal as a fourth signal, a combiner that combines the third signal and the fourth signal, a single pad t to which a bias voltage is supplied, a first bias circuit that connects the single pad to the first node in a direct-current manner and reduces leakage of the first signal to the single pad, and a second bias circuit that connects the single pad to the second node in a direct-current manner and reduces leakage of the second signal to the single pad.

An amplifier circuit according to an embodiment of the present disclosure includes a divider that divides an input signal into a first signal and a second signal, a first amplifier that has a first node receiving the first signal, amplifies the first signal received at the first node, and outputs an amplified first signal as a third signal, a second amplifier that has a second node receiving the second signal, amplifies the second signal received at the second node, and outputs an amplified second signal as a fourth signal, a combiner that combines the third signal and the fourth signal, a single pad to which a bias voltage is supplied, a first bias circuit that connects the single pad to the first node in a direct-current manner and reduces leakage of the first signal to the single pad, and a second bias circuit that connects the first node to the second node in a direct-current manner and reduces leakage of the first signal to the second node and leakage of the second signal to the first node.

### BRIEF DESCRIPTION OF THE DRAWINGS

FIG. 1 is a circuit diagram of an amplifier circuit according to a first embodiment.

FIG. 2 is a circuit diagram illustrating a first example of a bias circuit in the first embodiment.

FIG. 3 is a circuit diagram illustrating a second example of a bias circuit in the first embodiment.

FIG. 4 is a circuit diagram illustrating a third example of a bias circuit in the first embodiment.

FIG. 5 is a circuit diagram illustrating a first example of a divider in the first embodiment.

FIG. 6 is a circuit diagram illustrating a second example of a divider in the first embodiment.

FIG. 7 is a circuit diagram illustrating a third example of a divider in the first embodiment.

FIG. 8 is a circuit diagram of an amplifier circuit according to the first embodiment.

FIG. 9 is a circuit diagram of an amplifier circuit according to the first comparative example.

FIG. 10 is a circuit diagram of an amplifier circuit according to a second embodiment.

FIG. 11 is a circuit diagram illustrating a first example of a bias circuit in the second embodiment.

FIG. 12 is a circuit diagram illustrating a second example of a bias circuit in the second embodiment.

FIG. 13 is a circuit diagram illustrating a third example of a bias circuit in the second embodiment.

FIG. 14 is a circuit diagram illustrating a fourth example of a divider in the second embodiment.

FIG. 15 is a circuit diagram illustrating a fifth example of a divider in the second embodiment.

FIG. 16 is a circuit diagram of a circuit used in a simulation.

FIG. 17 is a diagram illustrating S21 and S41 in a simulation.

FIG. 18 is a diagram illustrating S43 and S23 in a simulation.

FIG. 19 is a circuit diagram of an amplifier circuit according to a third embodiment.

FIG. 20 is a circuit diagram illustrating a first example of a bias circuit in the third embodiment.

FIG. 21 is a circuit diagram illustrating a second example of a bias circuit in the third embodiment.

FIG. 22 is a circuit diagram illustrating an amplifier circuit according to a fourth embodiment.

### DETAILED DESCRIPTION

In the patent literature 1, a bias voltage is applied from a voltage current source 8 to input nodes of amplifiers 4 and 5, and a bias voltage is applied from a voltage current source 9 to output nodes of amplifiers 4 and 5. However, a specific method of applying the bias voltage from voltage current source 8 to the input nodes of amplifiers 4 and 5 is not described, and the amplifier circuit may be increased in size.

The present disclosure has been made in view of the above problems, and an object of the present disclosure is to reduce the size.

### DESCRIPTION OF EMBODIMENTS OF PRESENT DISCLOSURE

First, the contents of embodiments of the present disclosure will be listed and explained.
(1) An amplifier circuit according to an embodiment of the present disclosure includes a divider that divides an input signal into a first signal and a second signal, a first amplifier that has a first node receiving the first signal, amplifies the first signal received at the first node, and outputs an amplified first signal as a third signal, a second amplifier that has a second node receiving the second signal, amplifies the second signal received at the second node, and outputs an amplified second signal as a fourth signal, a path that connects the first node to the second node in a direct-current manner via the divider, and a combiner that combines the third signal and the fourth signal. The path is provided with a third node at one location to supply a bias voltage to the first amplifier and the second amplifier. This can reduce the number of pads and the number of bias circuits, and thus the size of the amplifier circuit can be reduced.
(2) The amplifier circuit according to the above (1) may further include a pad to which the bias voltage is supplied, and a bias circuit that connects the pad to the third node in a direct-current manner and reduces leakage of the first signal and the second signal to the pad. This can reduce the number of pads and the number of bias circuits, and thus the size of the amplifier circuit can be reduced.
(3) In the above (1) or (2), the divider may include a branch-line coupler including a first end receiving the input signal, a second end outputting the first signal, a third end located diagonally to the first end and outputting the second signal, and a fourth end located diagonally to the second end and terminated at a reference potential. Thus, the first node and the second node can be connected to each other in a direct-current manner via the divider.
(4) The amplifier circuit according to the above (3) may further include a capacitor having a first end connected to the fourth end of the branch-line coupler, and a resistor having a first end connected to a second end of the capacitor and a second end connected to the reference potential. This can reduce a direct current from flowing from the path to the reference potential.
(5) An amplifier circuit according to an embodiment of the present disclosure includes a divider that divides an input signal into a first signal and a second signal, a first amplifier that has a first node receiving the first signal, amplifies the first signal received at the first node, and outputs an amplified first signal as a third signal, a second amplifier that has a second node receiving the second signal, amplifies the second signal received at the second node. and outputs an amplified second signal as a fourth signal, a combiner that combines the third signal and the fourth signal, a single pad to which a bias voltage is supplied, a first bias circuit that connects the single pad to the first node in a direct-current manner and reduces leakage of the first signal to the single pad, and a second bias circuit that connects the single pad to the second node in a direct-current manner and reduces leakage of the second signal to the single pad. This can reduce the number of pads, and thus the size of amplifier circuit can be reduced.
(6) An amplifier circuit according to an embodiment of the present disclosure includes a divider that divides an input signal into a first signal and a second signal, a first amplifier that has a first node receiving the first signal, amplifies the first signal received at the first node, and outputs an amplified first signal as a third signal, a second amplifier that has a second node receiving the second signal, amplifies the second signal received at the second node, and outputs an amplified second signal as a fourth signal, a combiner that combines the third signal and the fourth signal, a single pad to which a bias voltage is supplied, a first bias circuit that connects the single pad to the first node in a direct-current manner and reduces leakage of the first signal to the single pad, and a second bias circuit that connects the first node to the second node in a direct-current manner and reduces leakage of the first signal to the second node and leakage of the second signal to the first node. This can reduce the number of pads, and thus the size of amplifier circuit can be reduced.
(7) In the above (5) or (6), the divider has a first end outputting the first signal and a second end outputting the second signal, and the first end of the divider and the second end of the divider do not have to be connected to each other in a direct-current manner via the divider. This can reduce the number of pads, and thus the size of amplifier circuit can be reduced.
(8) In the above (5) or (6), the divider has a first end outputting the first signal and a second end outputting the second signal, the first end of the divider and the second end of the divider may be connected to each other in a direct-current manner via the divider, and the amplifier circuit may further include a first capacitor having a first end connected to the divider and a second end connected to the first node, and a second capacitor having a first end connected to the divider and a second end connected to the second node. This can reduce the number of pads, and thus the size of amplifier circuit can be reduced.
(9) The amplifier circuit according to any one of the above (1) to (8) may further include another divider that divides a high frequency signal into the input signal and a fifth signal, and a control amplifier that amplifies the fifth signal and output an amplified fifth signal as a sixth signal. The combiner may modulate a load of the first amplifier and the second amplifier by using the sixth signal, combine the third signal, the fourth signal, and the sixth signal into a combined signal, and output the combined signal as an output signal. Thus, this can widen the band of the operating band.
(10) The amplifier circuit according to the above (9) may further include a direct-current path that connects an output node of the first amplifier to an output node of the control amplifier in a direct-current manner via the combiner. The direct-current path may be provided with a fourth node at one location to supply a bias voltage to the first amplifier and the control amplifier. This can reduce the number of pads and the number of bias circuits, and thus the size of the amplifier circuit can be reduced.

### DETAILS OF EMBODIMENTS OF PRESENT DISCLOSURE

Specific examples of an amplifier circuit according to embodiments of the present disclosure will be described below with reference to the drawings. It should be noted that the present disclosure is not limited to these examples, but is defined by the claims and is intended to include all modifications within the meaning and scope equivalent to the claims.

### First Embodiment

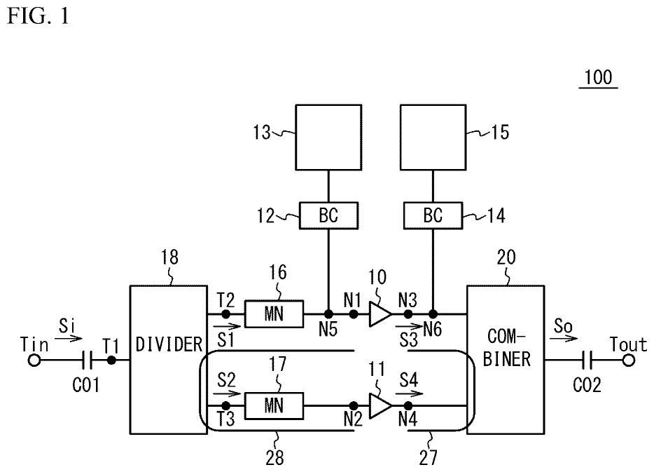

A first embodiment is an example of a balanced amplifier. FIG. 1 is a circuit diagram of an amplifier circuit according to a first embodiment. As illustrated in FIG. 1, in an amplifier circuit 100 of the first embodiment, amplifiers 10 and 11 are connected in parallel between an input terminal Tin and an output terminal Tout. A high frequency signal is received at input terminal Tin as an input signal Si. When amplifier circuit 100 is used in a base station of the mobile communication, the frequency of the high frequency signal is, for example, 0.5 GHz to 10 GHz. A capacitor C01 for direct current (DC) cutting is connected between input terminal Tin and a divider 18. Divider 18 divides input signal Si received at input terminal Tin into signals S1 (first signal) and S2 (second signal).

Signal S1 passes through a matching circuit (MN: Matching Network) 16 and is received at amplifier 10. In all figures, matching circuit is illustrated as “MN”. Matching circuit 16 matches an impedance when matching circuit 16 is viewed from divider 18 with an impedance when amplifier 10 is viewed from matching circuit 16. Amplifier 10 (first amplifier) has nodes N1 (first node) and N3. Amplifier 10 amplifies signal S1 received at node N1 and outputs amplified signal S1 to node N3 as a signal S3 (third signal). Signal S3 amplified by amplifier 10 is received at a combiner 20.

Signal S2 passes through a matching circuit 17 and is received at amplifier 11. Matching circuit 17 matches an impedance when matching circuit 17 is viewed from divider 18 with an impedance when amplifier 11 is viewed from matching circuit 17. Amplifier 11 (second amplifier) has nodes N2 (second node) and N4. Amplifier 11 amplifies signal S2 received at node N2 and outputs amplified signal S2 to node N4 as a signal S4 (fourth signal). Signal S4 amplified by amplifier 11 is received at combiner 20.

Combiner 20 combines signals S3 and S4 into a combined signal, and outputs the combined signal as an output signal So to output terminal Tout. A capacitor C02 for DC-cutting is connected between combiner 20 and output terminal Tout.

A path 28 connects nodes N1 and N2 to each other in a direct-current manner via matching circuits 16 and 17 and divider 18. Thus, nodes N1 and N2 are short-circuited in a direct-current manner and have substantially the same potential in a direct-current manner. A path 27 connects nodes N3 and N4 to each other in a direct-current manner via combiner 20. Thus, nodes N3 and N4 are short-circuited in a direct-current manner and have substantially the same potential in a direct-current manner.

A bias circuit (BC) 12 is connected between a node N5 in path 28 and a pad 13. Pad 13 is a pad for supplying an input bias voltage to nodes N1 and N2 which are input nodes of amplifiers 10 and 11. Bias circuit 12 connects pad 13 and node N5 to each other in a direct-current manner, and reduces leakage of signal S1 flowing through node N5 to pad 13. Nodes N1 and N2 are connected to each other in a direct-current manner by path 28. Thus, substantially the same input bias voltage is applied to nodes N1 and N2. Bias circuit 12 may be connected to any point on path 28.

A bias circuit 14 is connected between a node N6 in path 27 and a pad 15. Pad 15 is a pad for supplying an output bias voltage to nodes N3 and N4 which are output nodes of amplifiers 10 and 11. Bias circuit 14 connects pad 15 and node N6 to each other in a direct-current manner, and reduces leakage of signal S3 flowing through node N6 to pad 15. Nodes N3 and N4 are connected to each other in a direct-current manner by path 27. Thus, substantially the same output bias voltage is applied to nodes N3 and N4.

A matching circuit or a harmonic processing circuit may be connected between node N3 and combiner 20. A matching circuit or a harmonic processing circuit may be connected between node N4 and combiner 20. The matching circuit matches an impedance when the matching circuit is viewed from node N3 or N4 with an impedance when combiner 20 is viewed from the matching circuit. The harmonic processing circuit reflects a harmonic signal in signal S3 or S4 to node N3 or N4. The harmonic signal is, for example, a second harmonic wave or a third harmonic wave when the operating band of amplifier circuit 100 is set as a fundamental wave.

Amplifiers 10 and 11 are, for example, field effect transistors (FET), have sources connected to ground, receive the high frequency signals at gates, and output the high frequency signals from drains. The FET is, for example, a gallium nitride high electron mobility transistor (GaN HEMT) or a laterally diffused metal oxide semiconductor (LDMOS). Each of amplifiers 10 and 11 may be provided with multistage FETs. When amplifiers 10 and 11 are FETs, the bias voltage supplied to pads 13 and 15 is a gate bias voltage and a drain bias voltage, respectively.

When amplifier circuit 100 is a balanced amplifier, divider 18 divides input signal Si into signals S1 and S2 so that the amplitudes of signals S1 and S2 are substantially the same as each other, and the phase of signal S2 at a center frequency fo of the operating band is delayed by substantially 90 degrees from the phase of signal S1. Combiner 20 delays the phase of signal S3 by 90 degrees and combines signal S3 with signal S4. Amplifier circuit 100 may be an amplifier circuit other than the balanced amplifier.

### [Example of Bias Circuit]

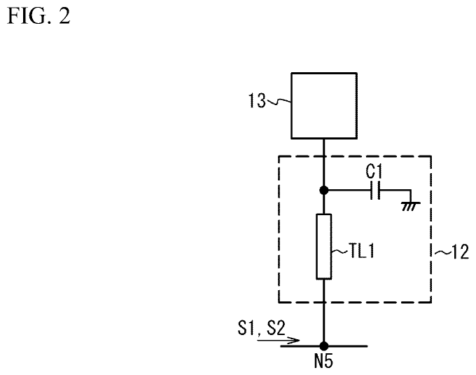

FIGS. 2 to 4 are circuit diagrams illustrating first to third examples of bias circuits in a first embodiment. As illustrated in FIG. 2, in the first example, bias circuit 12 includes a transmission line TL1 and a capacitor C1. A first end of transmission line TL1 is electrically connected to node N5, and a second end of transmission line TL1 is electrically connected to pad 13. Transmission line TL1 is a λ/4 transmission line. The electrical length of the λ/4 transmission line is, for example, λ/4 . Here, λ is the wavelength of center frequency fo of the operating band of amplifier circuit 100. The electrical length of the λ/4 transmission line does not have to be strictly λ/4, and may be, for example, 3λ/16 to 5λ/16, or 7λ/32 to 9λ/32. The same applies to the following embodiments. A capacitor C1 is shunt-connected to a node between transmission line TL1 and pad 13. Thus, the bias voltage supplied to pad 13 is supplied to node N5, and signal S1 or S2 passing through node N5 is less likely to leak to pad 13.

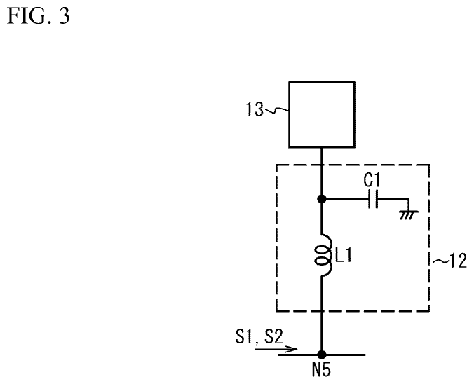

As illustrated in FIG. 3, in the second example, an inductor L1 is used instead of transmission line TL1 of FIG. 2. In the second example of FIG. 3, signal S1 or S2 passing through node N5 is less likely to leak to pad 13 by appropriately setting the inductance of inductor L1 and the capacitance of capacitor C1.

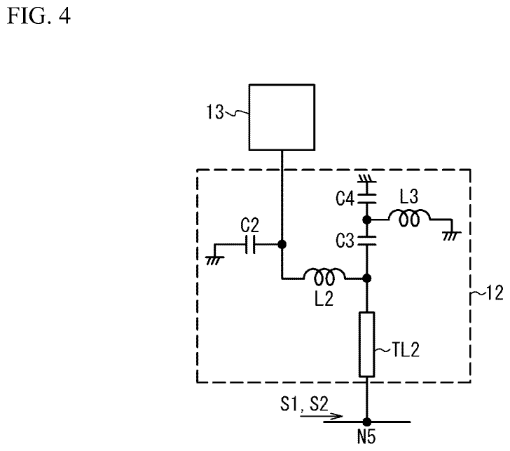

As illustrated in FIG. 4, in the third example, a composite right/left handed (CRLH) line is used. A transmission line TL2 and an inductor L2 are connected in series between node N5 and pad 13. A capacitor C2 is shunt-connected to a node between inductor L2 and pad 13. Capacitors C3 and C4 are connected in series between a node between transmission line TL2 and inductor L2 and a ground. An inductor L3 is shunt-connected to a node between capacitors C3 and C4. In the third example of FIG. 4, signal S1 or S2 passing through node N5 is less likely to leak to pad 13 by appropriately setting the inductances of inductors L2 and L3 and the capacitances of capacitors C2 to C4. A CRLH line other than the circuit of FIG. 4 may be used.

### [Example of Divider]

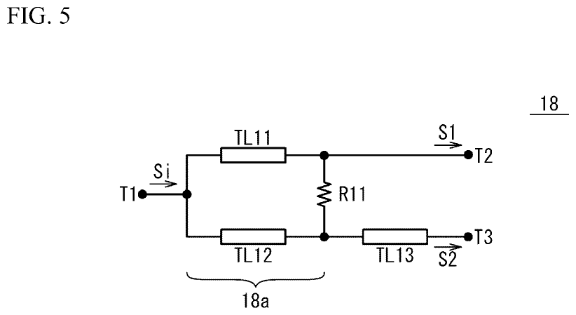

FIGS. 5 to 7 are circuit diagrams illustrating first to third examples of dividers in the first embodiment. As illustrated in FIG. 5, in first example, a Wilkinson divider is used as divider 18. A Wilkinson divider 18a includes transmission lines TL11, TL12 and a resistor R11. Transmission line TL11 is connected between an end T1 and an end T2, and transmission line TL12 is connected between the end T1 and an end T3. Transmission lines TL11 and TL12 are λ/4 transmission lines. The resistance of resistor R11 is, for example, twice the reference impedance. A transmission line TL13 is connected between transmission line TL12 and the end T3. Transmission line TL13 is a λ/4 transmission line. The Wilkinson divider divides input signal Si received at the end T1 into signals S1 and S2 having the same amplitude, and transmission line TL13 delays the phase of signal S2 at center frequency fo by approximately 90 degrees from the phase of signal S1. The ends T2 and T3 are connected to each other in a direct-current manner via transmission lines TL11 to TL13. Note that 90 degrees do not have to be strictly 90°, and may be, for example, 3λ/16 to 5λ/16, or 7λ/32 to 9λ/32 in terms of wavelength λ. The same applies to the following examples.

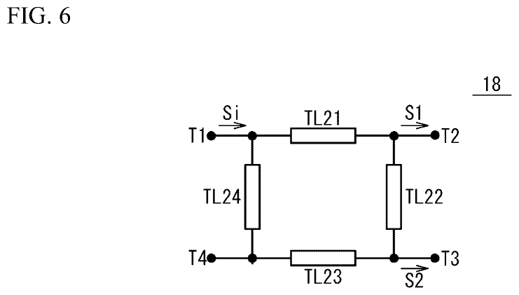

As illustrated in FIG. 6, in the second example, divider 18 uses a distributed constant branch-line coupler as a 90 degrees coupler. A transmission line TL21 is connected between an end T1 and an end T2. A transmission line TL22 is connected between the end T2 and an end T3. A transmission line TL23 is connected between the end T3 and an end T4. A transmission line TL24 is connected between the end T4 and the end T1. Transmission lines TL21 to TL24 are λ/4 transmission lines. Input signal Si received at the end T1 is divided into signals S1 and S2, which are output from the ends T2 and T3, respectively. The phase of signal S2 at center frequency fo is delayed by approximately 90 degrees from the phase of signal S1. The end T4 is connected to a reference potential via, for example, a reference impedance (for example, 50 Ω. The ends T2 and T3 are connected to each other in a direct-current manner via transmission lines TL21 to TL24.

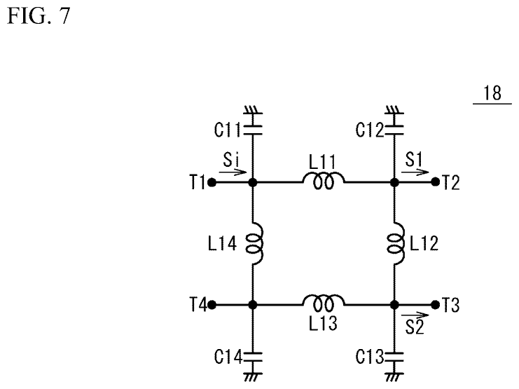

As illustrated in FIG. 7, in the third example, divider 18 uses a lumped constant type branch-line coupler. An inductor L11 is connected between an end T1 and an end T2. An inductor L12 is connected between the end T2 and an end T3. An inductor L13 is connected between the end T3 and an end T4. An inductor L14 is connected between the end T4 and the end T1. A node between inductors L14 and L11 is grounded via capacitor C11. A node between inductors L11 and L12 is grounded via capacitor C12. A node between inductors L12 and L13 is grounded via capacitor C13. A node between inductors L13 and L14 is grounded via capacitor C14. By appropriately setting the inductances from inductor L11 to L14 and the capacitances from capacitor C11 to C14, input signal Si received at the end T1 is substantially equally divided into signals S1 and S2, and signals S1 and S2 are output from the ends T2 and T3, respectively, and the phase of signal S2 at center frequency fo is delayed by substantially 90 degrees from the phase of signal S1. The end T4 is connected to a reference potential via a reference impedance, for example. The ends T2 and T3 are connected to each other in a direct-current manner via inductors L11 to L14.

Matching circuits 16 and 17 are passive circuits including inductors and capacitors. The capacitors are not connected in series to the paths through which each of signals S1 and S2 flow. Thus, the end T2 and node N1 are connected to each other in a direct-current manner, and the end T3 and node N2 are connected to each other in a direct-current manner. Matching circuits 16 and 17 are, for example, inductors connected in series, π-type circuits having CLC configurations, T-type circuits having LCL configurations, L-type circuits having LC configurations, or circuits obtained by combining these circuits.

### [Example of Amplifier Circuit Using 90 Degrees Coupler]

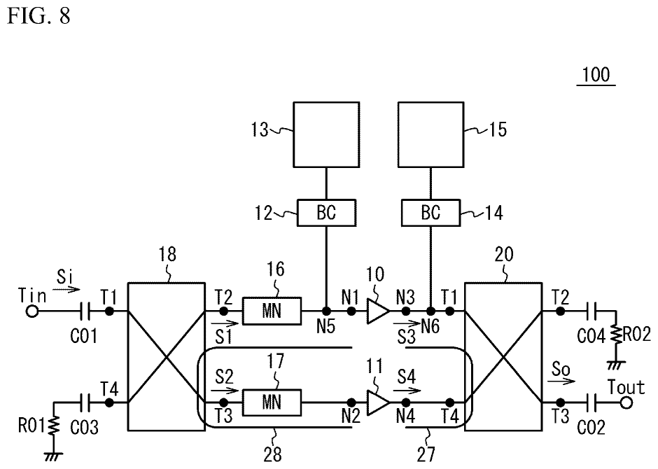

FIG. 8 is a circuit diagram of an amplifier circuit according to a first embodiment, and illustrates an example in which the 90 degrees coupler of FIG. 6 is used for divider 18 and combiner 20. As illustrated in FIG. 8, an end T1 of divider 18 is connected to input terminal Tin via capacitor C01 for DC-cutting. An end T2 of divider 18 is connected to node N1 via matching circuit 16. An end T3 of divider 18 is connected to node N2 via matching circuit 17. An end T4 of divider 18 is terminated via a capacitor C03 for DC-cutting and a resistor R01. An end T1 of combiner 20 is electrically connected to node N3. An end T2 of combiner 20 is terminated via a capacitor C04 for DC-cutting and a resistor R02. An end T3 of combiner 20 is connected to output terminal Tout via capacitor C02 for DC-cutting. An end T4 of combiner 20 is connected to node N4. The resistances of resistors R01 and R02 are reference impedances (for example, 50 Ω. In combiner 20, signals S3 and S4 received at the end T1 and the end T4 are combined into output signal So, with the phase of signal S3 at center frequency fo being delayed by approximately 90 degrees with respect to the phase of signal S4.

Path 28 connects nodes N1 and N2 to each other in a direct-current manner via divider 18. Thus, by connecting bias circuit 12 to node N5 at any position of path 28, substantially the same input bias voltage can be applied to amplifiers 10 and 11. Path 27 connects nodes N3 and N4 to each other in a direct-current manner via combiner 20. Thus, by connecting bias circuit 14 to node N6 at any position of path 27, substantially the same bias voltage can be applied to amplifiers 10 and 11. Capacitor C01 can reduce a direct current from flowing to input terminal Tin due to the input bias voltage. Capacitor C02 can reduce a direct current from flowing to output terminal Tout due to the output bias voltage. Capacitors C03 and C04 can reduce direct currents from flowing through resistors R01 and R02.

### First Comparative Example

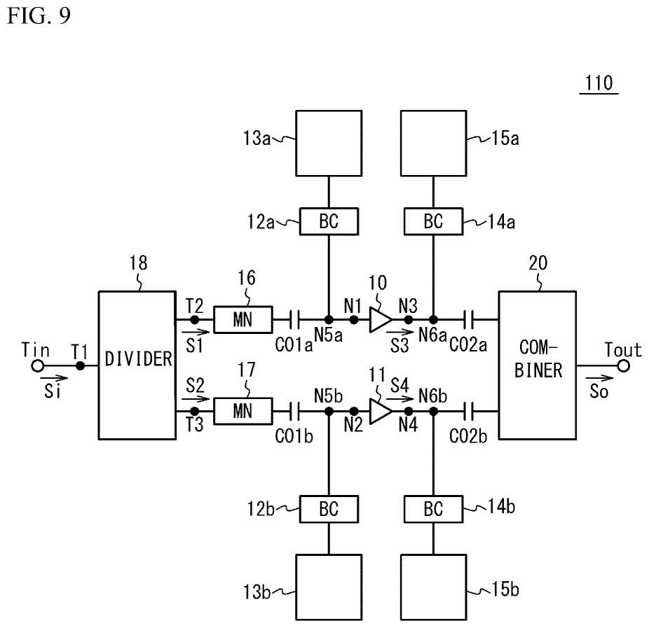

FIG. 9 is a circuit diagram of an amplifier circuit according to a first comparative example. As illustrated in FIG. 9, in an amplifier circuit 110 of first comparative example, a capacitor C01a for DC-cutting is connected between divider 18 and node N1, and a capacitor C01b for DC-cutting is connected between divider 18 and node N2. A capacitor C02a for DC-cutting is connected between combiner 20 and node N3, and a capacitor C02b for DC-cutting is connected between combiner 20 and node N4. A pad 13a is connected to node N5a between node N1 and capacitor C01a via a bias circuit 12a, and a pad 13b is connected to node N5b between node N2 and capacitor C01b via bias circuit 12b. A pad 15a is connected to a node N6a between node N3 and capacitor C02a via a bias circuit 14a, and a pad 15b is connected to a node N6b between node N4 and capacitor C02b via a bias circuit 14b.

In first comparative example, nodes N1 and N2 are not connected to each other in a direct-current manner, and nodes N3 and N4 are not connected to each other in a direct-current manner. Thus, pads 13a and 13b are connected to nodes N5a and N5b separately via bias circuits 12a and 12b, respectively. Pads 15a and 15b are connected to nodes N5a and N6b separately via bias circuits 14a and 14b, respectively. As described above, amplifier circuit 110 is increased in size because two pads 13a and 13b, two bias circuits 12a and 12b, two pads 15a and 15b, and two bias circuits 14a and 14b are provided.

A Doherty amplifier circuit is known as an amplifier circuit in which amplifiers are connected in parallel between input terminal Tin and output terminal Tout. In the Doherty amplifier circuit, the main amplifier is operated in class A or class AB, and the peak amplifier is operated in class C. Thus, the input bias voltages of the main amplifier and the peak amplifier are made different. Thus, a bias circuit for applying an input bias voltage to the main amplifier and a bias circuit for applying an input bias voltage to the peak amplifier are separately provided. However, when the input bias voltages of amplifiers 10 and 11 can be made equal as in the first embodiment and first comparative example, the amplifier circuit is increased in size when two pads 13a and 13b and two bias circuits 12a and 12b are provided as in first comparative example.

Pad 13 is a metal layer such as a copper layer, a gold layer, or an aluminum layer provided on the dielectric substrate. A bonding wire, a bump, or the like is bonded to pad 13. Thus, the size of pad 13 is 50 μm×50 μm or more, and as an example, the size is 100 μm×100 μm, which is very large. Thus, when two pads 13a and 13b are provided as in first comparative example, the amplifier circuit is increased in size.

### [Description of First Embodiment]

According to the first embodiment, path 28 that connects nodes N1 and N2 to each other in a direct-current manner is provided with node N5 (third node) at only one location to supply the input bias voltage to amplifiers 10 and 11. Thus, amplifiers 10 and 11 can be supplied with the input bias voltage by using one bias circuit 12 and one pad 13. Thus, the size of amplifier circuit 100 can be reduced. In FIGS. 1 and 8, node N5 is provided between divider 18 and node N1, but may be provided between divider 18 and node N2.

Bias circuit 12 connects pad 13 and node N5 to each other in a direct-current manner, and reduces leakage of signals S1 and S2 to pad 13. As described above, the number of pads 13 and bias circuits 12 can be reduced, and the size of amplifier circuit 100 can be reduced. For example, an absolute value of an impedance (for example, resistance) at the direct-current between pad 13 and node N5 is smaller than an absolute value of an impedance at center frequency fo of the operating band between pad 13 and node N5, for example, 1/10 times or less, 1/100 times or less, or 1/1000 times or less. Further, the leakage from node N5 to pad 13 at center frequency fo is −20 dB or less, −40 dB or less, or −60 dB or less. The same applies to bias circuits in the following embodiments.

As illustrated in FIG. 8, a branch-line coupler is used as divider 18. Input signal Si is received at an end T1 (first end) of the branch-line coupler. Signal S1 is output from an end T2 (second end). An end T3 (third end) is located diagonally to the end T1, and signal S2 is output from the end T3. An end T4 (fourth end) is located diagonally to the end T2 and is terminated at the reference potential. Thus, nodes N1 and N2 are connected by a direct-current path 28 via divider 18.

A first end of capacitor C03 is connected to the end T4. A first end of resistor R01 is connected to a second end of capacitor C03, and a second end of resistor R01 is connected to the reference potential. This can reduce a direct current from flowing from path 28 to the reference potential via resistor R01. The resistance of resistor R01 is a reference impedance (for example, 50 Ω. The resistance of resistor R01 do not have to be strictly the reference impedance, and may be, for example, 0.8 times to 1.2 times the reference impedance.

### Second Embodiment

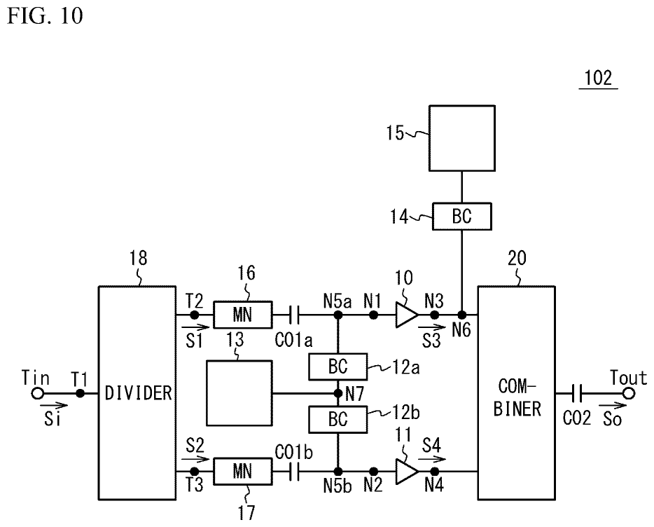

FIG. 10 is a circuit diagram of an amplifier circuit according to a second embodiment. As illustrated in FIG. 10, in an amplifier circuit 102 of the second embodiment, node N5a is provided between node N1 and an end T2, and node N5b is provided between node N2 and an end T3. Capacitor C01a for DC-cutting is provided between node N5a and the end T2, and capacitor C01b for DC-cutting is provided between node N5b and the end T3.

Bias circuit 12a is provided between nodes N5a and N7, and bias circuit 12b is provided between nodes N5b and N7. Pad 13 is electrically connected to node N7. Bias circuit 12a connects pad 13 and node N5a to each other in a direct-current manner, and reduces leakage of signal S1 flowing through node N5a to pad 13 and node N5b. Bias circuit 12b connects pad 13 and node N5b to each other in a direct-current manner, and reduces leakage of signal S2 flowing through node N5b to pad 13 and node N5a. The other circuit configuration is the same as that of FIG. 1 of the first embodiment, and the description thereof will be omitted.

### [Example of Bias Circuit]

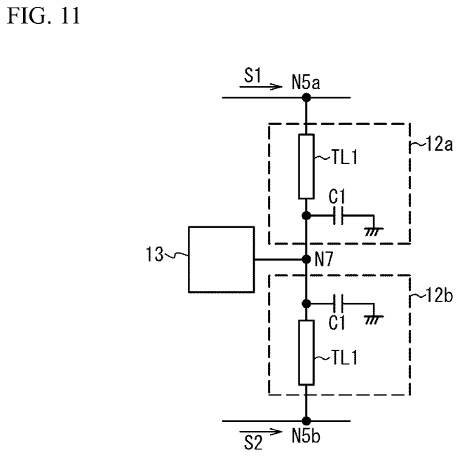

FIGS. 11 to 13 are circuit diagrams illustrating first to third examples of the bias circuits according to a second embodiment. As illustrated in FIG. 11, in the first example, each of bias circuits 12a and 12b has the same circuit configuration as bias circuit 12 in FIG. 2. A first end of transmission line TL1 is connected to node N5a in bias circuit 12a, a first end of transmission line TL1 is connected to node N5b in bias circuit 12b, and second ends of transmission lines TL1 are connected to node N7. Capacitor C1 is shunt-connected to a node between node N7 and transmission line TL1. Thus, the bias voltage supplied to pad 13 is supplied to nodes N5a and N5b, and signal S1 passing through node N5a and signal S2 passing through node N5b are less likely to leak to pad 13.

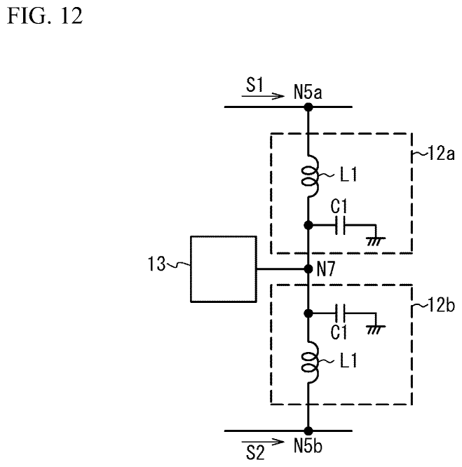

As illustrated in FIG. 12, in the second example, each of bias circuits 12a and 12b has the same circuit configuration as bias circuit 12 in FIG. 3. In each of bias circuits 12a and 12b, inductor L1 is used instead of transmission line TL1 of FIG. 11. Also in the second example of FIG. 12, by appropriately setting the inductance of inductor L1 and the capacitance of capacitor C1, signal S1 passing through node N5a and signal S2 passing through node N5b are less likely to leak to pad 13.

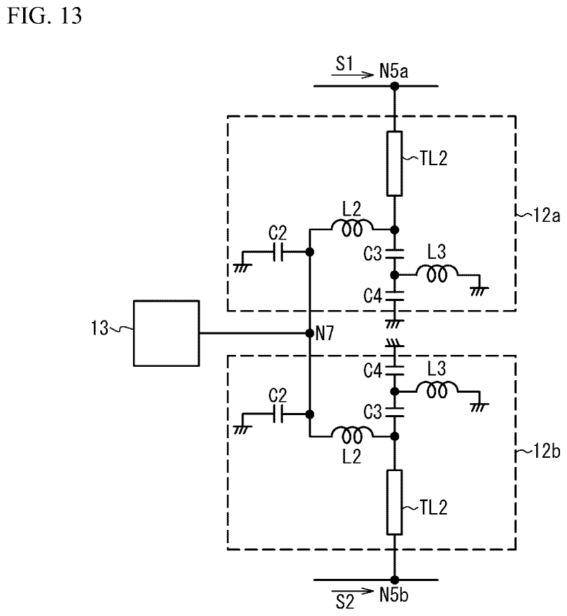

As illustrated in FIG. 13, in the third example, each of bias circuits 12a and 12b has the same circuit configuration as bias circuit 12 of FIG. 4. Also in the third example of FIG. 13, by appropriately setting the inductances of inductors L2 and L3 and the capacitances of capacitors C2 to C4, signal S1 passing through node N5a and signal S2 passing through node N5b are less likely to leak to pad 13. A CRLH line other than the circuit of FIG. 13 may be used.

### [Example of Divider]

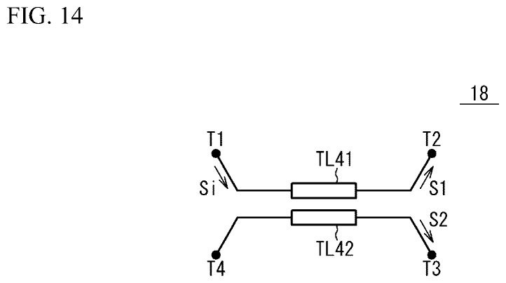

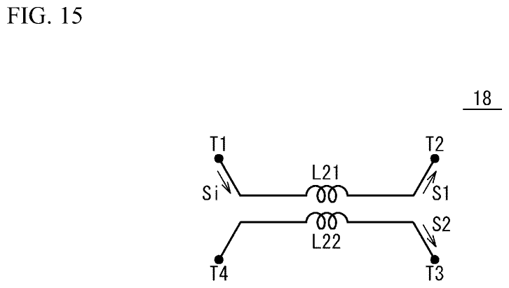

FIGS. 14 and 15 are circuit diagrams illustrating fourth and fifth examples of dividers in a second embodiment. As illustrated in FIG. 14, in the fourth example, divider 18 is a distributed coupling type coupler in which transmission lines TL41 and TL42 are electromagnetically coupled. Input signal Si received at an end T1 is divided into signals S1 and S2, which are output to an end T2 and an end T3, respectively. An end T4 is connected to a reference potential via a reference impedance, for example. The phase of signal S2 at center frequency fo is delayed by approximately 90 degrees from the phase of signal S1. By appropriately setting a coupling coefficient between transmission lines TL41 and TL42, the ratio of the amplitudes of signals S1 and S2 can be appropriately set.

As illustrated in FIG. 15, in the fifth example, divider 18 is a close-wound coil coupler in which inductors L21 and L22 are electromagnetically coupled. Input signal Si received at an end T1 is divided into signals S1 and S2, and the phase of signal S2 at center frequency fo is delayed by approximately 90 degrees from the phase of signal S1. By appropriately setting the inductances of inductors L21 and L22 and a coupling coefficient between inductors L21 and L22, the ratio of the amplitudes of signals S1 and S2 can be appropriately set. An end T4 is connected to a reference potential via a reference impedance, for example.

According to the second embodiment, pad 13 to which the bias voltage is supplied is single pad 13. Bias circuit 12a (first bias circuit) connects single pad 13 and node N1 to each other in a direct-current manner, and reduces leakage of signal S1 to single pad 13. Bias circuit 12b (second bias circuit) connects single pad 13 and node N2 to each other in a direct-current manner, and reduces leakage of signal S2 to single pad 13. Thus, the number of pads 13 can be reduced to one as compared with the first comparative example of FIG. 9. Thus, the size of amplifier circuit 102 can be reduced.

When the divider of the fourth example of FIG. 14 or the divider of the fifth example of FIG. 15 is used as divider 18 of FIG. 10, ends T2 and T3 are not connected to each other in a direct-current manner via divider 18. Thus, it is difficult to reduce the number of bias circuits 12 to one as in the first embodiment. Thus, single pad 13 and bias circuits 12a and 12b as described in FIGS. 11 to 13 are used. Thus, the number of pads 13 can be reduced to one as compared with the first comparative example, and the size of amplifier circuit 102 can be reduced. When the fourth example of FIG. 14 or the fifth example of FIG. 15 is used as divider 18, the capacitor for DC-cutting may be provided between input terminal Tin and divider 18, instead of being provided between divider 18 and nodes N1 and N2.

One of the dividers of the first to third examples of the circuit configurations described in FIGS. 5 to 7 may be used as divider 18 of FIG. 10. As illustrated in FIG. 10, a first end of capacitor C01a (first capacitor) is connected to divider 18, and a second end of capacitor C01a is connected to node N1. A first end of capacitor C01b (second capacitor) is connected to divider 18, and a second end of capacitor C01b is connected to node N2. In this case, nodes N1 and N2 are separated from each other in a direct-current manner. Thus, single pad 13 and bias circuits 12a and 12b as described in FIGS. 11 to 13 are used. Thus, the number of pads 13 can be reduced to one as compared with the first comparative example, and the size of amplifier circuit 102 can be reduced.

### [Simulation]

In the second embodiment, the passing characteristics of nodes N5a and N5b and the isolation characteristics between nodes N5a and N5b were simulated.

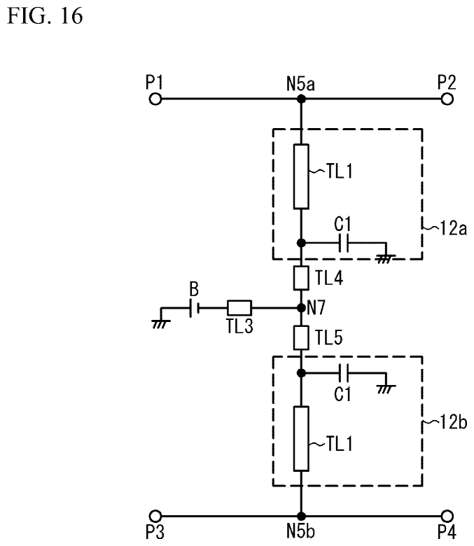

FIG. 16 is a circuit diagram of a circuit used in a simulation. As illustrated in FIG. 16, node N5a is provided in the path between ports P1 and P2. Node N5b is provided in a path between ports P3 and P4. Bias circuit 12a and a transmission line TL4 are connected in series between node N5a and node N7. Bias circuit 12b and a transmission line TL5 are connected in series between node N5b and node N7. The circuit configurations of bias circuits 12a and 12b are the same as those in the first example of FIG. 11. A transmission line TL3 is provided between node N7 and a power source B. Transmission lines TL3 to TL5 correspond to lines that electrically connect node N7 to power source B and bias circuits 12a and 12b, respectively.

A characteristic impedance at 3.5 GHz of each of transmission lines TL1 and TL3 to TL5 was set to 80 Ω, the electrical length at 3.5 GHz of transmission line TL1 was converted into phase and set to 90 degrees, and the electrical length at 3.5 GHz of each of transmission lines TL3 to TL5 was converted into phase and set to 5 degrees. The capacitance of capacitor C1 was set to 100 pF, and the bias voltage of the direct-current supplied by power source B was −2.6 V. Ports P1 to P4 were terminated by 50 Ω.

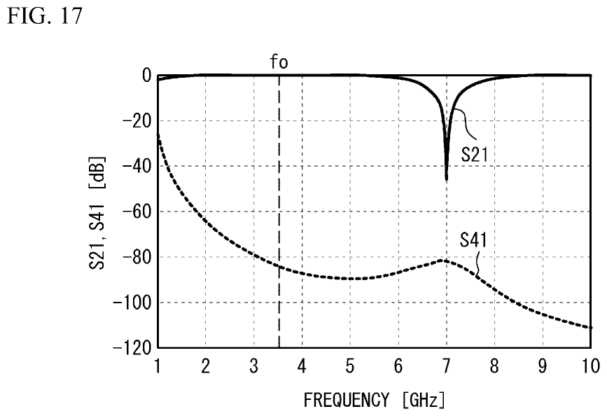

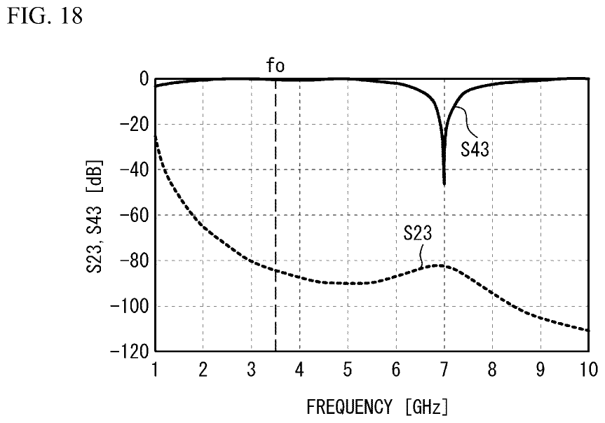

FIG. 17 is a diagram illustrating S21 and S41 in a simulation. FIG. 18 is a diagram illustrating S43 and S23 in a simulation. S21, S41, S43 and S23 correspond to S parameters between the respective ports, and in FIG. 17 and FIG. 18, absolute values of S21, S41, S43 and S23 are expressed in dB. S21 indicates a passing characteristic from port P1 to P2, S41 indicates an isolation characteristic from port P1 to P4, S43 indicates a passing characteristic from port P3 to P4, and S23 indicates an isolation characteristic from port P3 to P2. Frequency fo corresponding to the center frequency of the operating band of the amplifier circuit is 3.5 GHZ.

As illustrated in FIGS. 17 and 18, S21 and S43 at frequency fo are almost 0 dB, and there is almost no loss of signals S1 and S2 at nodes N5a and N5b. The reason why S21 and S43 are minimized at 7 GHz is that the electrical length of transmission line TL1 corresponds to 1/2 of the wavelength at 7 GHz. S41 and S23 at frequency fo are substantially −80 dB or less, and the isolation characteristic is good.

As in the simulation described above, in the second embodiment, it is possible to reduce the leakage of signal S1 to node N5a and the leakage of signal S2 to node N5b while reducing the loss of signals S1 and S2 at nodes N5a and N5b.

### Third Embodiment

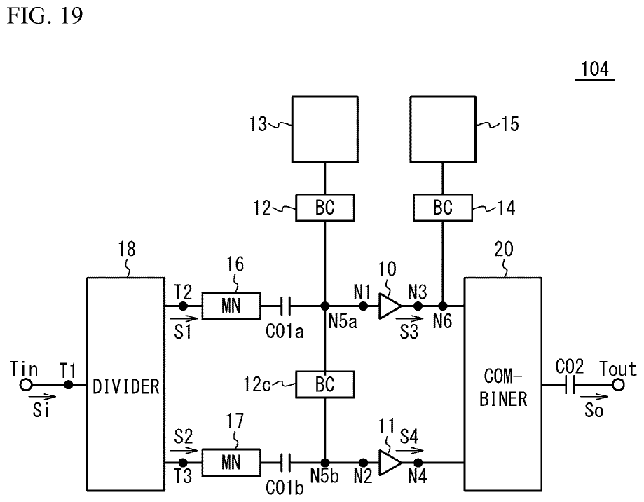

FIG. 19 is a circuit diagram of an amplifier circuit according to a third embodiment. As illustrated in FIG. 19, in an amplifier circuit 104 of the third embodiment, bias circuit 12 is provided between pad 13 and node N5a, and a bias circuit 12c is provided between nodes N5a and N5b. Bias circuit 12 connects pad 13 and node N5a to each other in a direct-current manner, and reduces leakage of signal S1 flowing through node N5a to pad 13. Bias circuit 12c connects nodes N5a and N5b to each other in a direct-current manner, reduces leakage of signal S1 flowing through node N5a to node N5b, and reduces leakage of signal S2 flowing through node N5b to node N5a. The other circuit configuration is the same as that of FIG. 10 of the second embodiment, and the description thereof will be omitted.

### [Example of Bias Circuit]

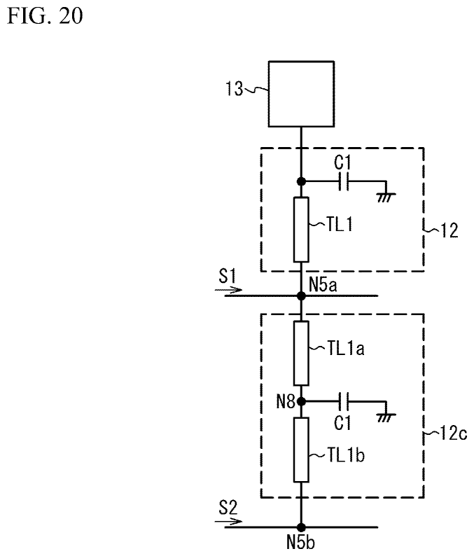

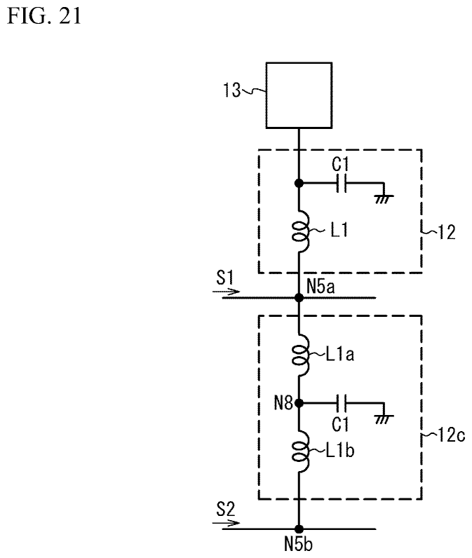

FIGS. 20 and 21 are circuit diagrams illustrating first and second examples of bias circuits in a third embodiment. As illustrated in FIG. 20, in the first example, bias circuit 12 has the same circuit configuration as bias circuit 12 of FIG. 2. Bias circuit 12 supplies the bias voltage supplied to pad 13 to node N5a, and reduces leakage of signal S1 passing through node N5a to pad 13.

In bias circuit 12c, a first end of a transmission line TL1a is electrically connected to node N5a, and a second end of transmission line TL1a is connected to a node N8. A first end of a transmission line TL1b is electrically connected to node N5b, and a second end of transmission line TL1b is connected to node N8. Capacitor C1 is shunt-connected to node N8. Transmission lines TL1a and TL1b are λ/4 transmission lines. Bias circuit 12c supplies the bias voltage supplied to node N5a to node N5b, reduces leakage of signal S1 passing through node N5a to node N5b, and reduces leakage of signal S2 passing through node N5b to node N5a.

As illustrated in FIG. 21, in the second example, inductors L1, L1a and L1b are used instead of transmission lines TL1, TL1a and TL1b of FIG. 20, respectively. By appropriately setting the inductances of inductors L1, L1a, and L1b and the capacitances of capacitor C1, signal S1 passing through node N5a is less likely to leak to pad 13 and node N5b, and signal S2 passing through node N5b is less likely to leak to node N5a. Bias circuits 12 and 12c may include CRLH lines.

According to the third embodiment, pad 13 to which the bias voltage is supplied is single pad 13. Bias circuit 12 (first bias circuit) connects single pad 13 and node N1 to each other in a direct-current manner, and reduces leakage of signal S1 to single pad 13. Bias circuit 12c (second bias circuit) connects nodes N1 and N2 to each other in a direct-current manner, reduces leakage of signal S1 to node N2, and reduces leakage of signal S2 to node N1. Thus, the number of pads 13 can be reduced to one as compared with the first comparative example of FIG. 9. Thus, the size of amplifier circuit 104 can be reduced.

The divider of the fourth example of FIG. 14 or the divider of the fifth example of FIG. 15 may be used as divider 18 of FIG. 10 of the second embodiment and FIG. 19 of the third embodiment. In this case, ends T2 and T3 are not connected to each other in a direct-current manner via divider 18. Thus, it is difficult to reduce the number of bias circuits 12 to one as in the first embodiment. Thus, single pad 13 and bias circuits 12 and 12c as described in FIGS. 20 and 21 are used. Thus, the number of pads can be reduced to one as compared with first comparative example, and the size of amplifier circuit 104 can be reduced.

Any one of the dividers of the first to third examples of the circuit configurations described in FIGS. 5 to 7 may be used as divider 18 of FIG. 10 of the second embodiment and FIG. 19 of the third embodiment. In this case, as illustrated in FIG. 19, when capacitors C01a and C01b are provided, nodes N1 and N2 are separated in a direct-current manner. Thus, single pad 13 and bias circuits 12 and 12c as described in FIGS. 20 and 21 are used. Thus, the number of pads can be reduced to one as compared with first comparative example, and the size of amplifier circuit 104 can be reduced.

### Fourth Embodiment

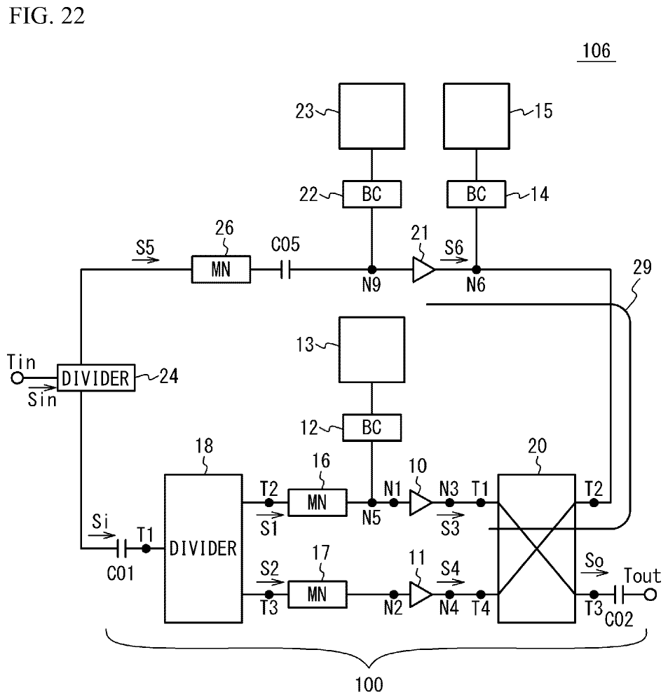

A fourth embodiment is an example of a load modulated balanced amplifier (LMBA). FIG. 22 is a circuit diagram of an amplifier circuit according to the fourth embodiment. As illustrated in FIG. 22, in an amplifier circuit 106 of the fourth embodiment, a control amplifier 21 and amplifiers 10 and 11 are connected in parallel between input terminal Tin and output terminal Tout. A high frequency signal is received at input terminal Tin as an input signal Sin. A divider 24 (another divider) divides input signal Sin received at input terminal Tin into a signal S5 (fifth signal) and input signal Si.

Signal S5 is received at control amplifier 21 via a matching circuit 26 and a capacitor C05. Matching circuit 26 matches an impedance when matching circuit 26 is viewed from divider 24 with an impedance when control amplifier 21 is viewed from matching circuit 26. Capacitor C05 is a capacitor for DC-cutting. Control amplifier 21 amplifies signal S5 and outputs the amplified signal as a signal S6 (sixth signal). Signal S6 amplified by control amplifier 21 is output to an end T2 of combiner 20.

A bias circuit 22 is provided between a node N9, which is located between control amplifier 21 and capacitor C05, and a pad 23. Pad 23 is a pad for supplying an input bias voltage to the input node of control amplifier 21. Bias circuit 22 connects pad 23 and node N9 to each other in a direct-current manner, and reduces leakage of signal S5 flowing through node N9 to pad 23.

Bias circuit 14 is provided between node N6, which is located between control amplifier 21 and the end T2 of combiner 20, and pad 15. Pad 15 is a pad for supplying an output bias voltage to the output nodes of control amplifier 21 and amplifiers 10 and 11. Bias circuit 14 connects pad 15 and node N6 to each other in a direct-current manner, and reduces leakage of signal S6 flowing through node N5 to pad 15.

Input signal Si divided by divider 24 is received at amplifier circuit 100. Amplifier circuit 100 is the same as amplifier circuit 100 of the first embodiment except that bias circuit 14 or pad 15 are not provided, combiner 20 is the 90 degrees coupler of FIG. 5, and signal S6 is received at the end T2 of combiner 20, and thus the description thereof will be omitted.

Control amplifier 21 corresponds to a main amplifier of the Doherty amplifier circuit, and amplifiers 10 and 11 correspond to peak amplifiers of the Doherty amplifier circuit. Control amplifier 21 operates in class AB or class B, and amplifiers 10 and 11 operate in class C. When the input power of input signal Sin is small, control amplifier 21 mainly amplifies input signal Sin. When the input power increases, amplifiers 10 and 11 amplify the peak of input signal Sin in addition to control amplifier 21. Thus, control amplifier 21 and amplifiers 10 and 11 amplify input signal Sin.

When the power of input signal Si is small and amplifiers 10 or 11 are not operating, signal S6 received at the end T2 of combiner 20 is divided into two signals S6/2 toward the end T1 and an end T4, respectively. The phase of signal S6/2 at the end T4 is delayed by 90 degrees from the phase of signal S6/2 at the end T1. Signals S6/2 are reflected at the ends T1 and T4. Signals S6/2 are combined at an end T3. The phase of signal S6/2 reflected at the end T1 is delayed by 90 degrees from the phase of signal S6/2 reflected at the end T4. Thus, the phases of two signals S6/2 are aligned at the end T3, and signal S6 is combined. The combined signal S6 is output to output terminal Tout as output signal So. At this time, a reflection coefficient when combiner 20 is viewed from amplifiers 10 and 11 is close to 1, and the load impedances of amplifiers 10 and 11 are substantially high.

When the power of input signal Sin is large and amplifiers 10 and 11 are operating, signal S4 is delayed in phase by 90 degrees from signal S3. Signal S6/2 at the end T4 is delayed in phase by 90 degrees from signal S6/2 at the end T1. Signal S3+S6/2 combined at the end T1 and signal S4+S6/2 combined at the end T4 are combined at the end T3. Combined signal S3+S4+S6 is output to output terminal Tout as output signal So. At this time, the reflection coefficient when combiner 20 is viewed from amplifiers 10 and 11 is smaller than 1, and the reflection coefficient decreases as the amplitudes of signals S3 and S4 increase. Thus, the load impedances of amplifiers 10 and 11 are substantially reduced. As described above, combiner 20 modulates the load impedances when combiner 20 is viewed from amplifiers 10 and 11, depending on the amplitudes of signals S3 and S4.

In the Doherty amplifier circuit, a combiner that combines a signal amplified by the main amplifier and a signal amplified by the peak amplifier includes a λ/4 line as an impedance converter. The load impedance of the main amplifier is modulated using the λ/4 line. In this case, when the frequency changes, the electrical length of the λ/4 line deviates from λ/4 , and thus it is difficult to widen the operating band. For example, the fractional bandwidth of a combiner using a λ/4 line is about 8%.

In the LMBA as in the fourth embodiment, combiner 20 modulates the loads of amplifiers 10 and 11 by using signal S6, combines signals S3, S4, and S6 into a combined signal, and outputs the combined signal as output signal So. This can widen the band of the operating band. For example, the fractional bandwidth of the 90 degrees coupler is 120% at the maximum in a commercially available 90 degrees hybrid coupler.

In the LMBA, the input bias voltage of amplifier 10 and the input bias voltage of amplifier 11 can be made substantially the same. Thus, the size of amplifier circuit 106 can be reduced by using any one of the amplifier circuits of the first to third embodiments as the amplifier circuit including amplifiers 10 and 11.

A direct-current path 29 connects node N3 of amplifier 10 and the output node of control amplifier 21 to each other in a direct-current manner via combiner 20. Direct-current path 29 is provided with node N6 (fourth node) at only one location to supply a bias voltage to amplifier 10 and control amplifier 21. Thus, the number of pads 15 for applying the output bias voltage to amplifier 10 and control amplifier 21, and the number of bias circuits 14 can be reduced to one each. Thus, the size of amplifier circuit 106 can be reduced.

Direct-current path 29 may connect nodes N3 and N4 and the output node of control amplifier 21 to each other in a direct-current manner via combiner 20. Direct-current path 29 may be provided with node N6 at only one location to supply the bias voltages to amplifiers 10 and 11 and control amplifier 21. Thus, the number of pads 15 and bias circuits 14 for applying the output bias voltages to amplifiers 10 and 11 and control amplifier 21 can be reduced to one each. Thus, the size of amplifier circuit 106 can be reduced.

The embodiments disclosed here should be considered illustrative in all respects and not restrictive. The present disclosure is not limited to the specific embodiments described above, but various variations and changes are possible within the scope of the gist of the present disclosure as described in the claims.

What is claimed is:

1. An amplifier circuit comprising:
a divider that divides an input signal into a first signal and a second signal;
a first amplifier that has a first node receiving the first signal, amplifies the first signal received at the first node, and outputs an amplified first signal as a third signal;
a second amplifier that has a second node receiving the second signal, amplifies the second signal received at the second node, and outputs an amplified second signal as a fourth signal;
a path that connects the first node to the second node in a direct-current manner via the divider; and
a combiner that combines the third signal and the fourth signal, wherein
the path is provided with a third node at one location to supply a bias voltage to the first amplifier and the second amplifier.

2. The amplifier circuit according to claim 1, further comprising:
a pad to which the bias voltage is supplied; and
a bias circuit that connects the pad to the third node in a direct-current manner and reduces leakage of the first signal and the second signal to the pad.

3. The amplifier circuit according to claim 1, wherein
the divider includes a branch-line coupler that includes a first end receiving the input signal, a second end outputting the first signal, a third end located diagonally to the first end and outputting the second signal, and a fourth end located diagonally to the second end and terminated at a reference potential.

4. The amplifier circuit according to claim 3, further comprising:
a capacitor having a first end connected to the fourth end of the branch-line coupler; and
a resistor having a first end connected to a second end of the capacitor and a second end connected to the reference potential.

5. An amplifier circuit comprising:
a divider that divides an input signal into a first signal and a second signal;
a first amplifier that has a first node receiving the first signal, amplifies the first signal received at the first node, and outputs an amplified first signal as a third signal;
a second amplifier that has a second node receiving the second signal, amplifies the second signal received at the second node, and outputs an amplified second signal as a fourth signal;
a combiner that combines the third signal and the fourth signal;
a single pad to which a bias voltage is supplied;
a first bias circuit that connects the single pad to the first node in a direct-current manner and reduces leakage of the first signal to the single pad; and
a second bias circuit that connects the single pad to the second node in a direct-current manner and reduces leakage of the second signal to the single pad.

6. An amplifier circuit comprising:
a divider that divides an input signal into a first signal and a second signal;
a first amplifier that has a first node receiving the first signal, amplifies the first signal received at the first node, and outputs an amplified first signal as a third signal;
a second amplifier that has a second node receiving the second signal, amplifies the second signal received at the second node, and outputs an amplified second signal as a fourth signal;
a combiner that combines the third signal and the fourth signal;
a single pad to which a bias voltage is supplied;
a first bias circuit that connects the single pad to the first node in a direct-current manner and reduces leakage of the first signal to the single pad; and
a second bias circuit that connects the first node to the second node in a direct-current manner and reduces leakage of the first signal to the second node and leakage of the second signal to the first node.

7. The amplifier circuit according to claim 5, wherein
the divider has a first end outputting the first signal and a second end outputting the second signal, and
the first end of the divider and the second end of the divider are not connected to each other in a direct-current manner via the divider.

8. The amplifier circuit according to claim 5, wherein
the divider has a first end outputting the first signal and a second end outputting the second signal,
the first end of the divider and the second end of the divider are connected to each other in a direct-current manner via the divider, and
the amplifier circuit further comprises:
a first capacitor having a first end connected to the divider and a second end connected to the first node; and
a second capacitor having a first end connected to the divider and a second end connected to the second node.

9. The amplifier circuit according to claim 1, further comprising:
another divider that divides a high frequency signal into the input signal and a fifth signal; and
a control amplifier that amplifies the fifth signal and outputs an amplified fifth signal as a sixth signal, wherein
the combiner that modulates a load of the first amplifier and the second amplifier by using the sixth signal, combines the third signal, the fourth signal, and the sixth signal into a combined signal, and outputs the combined signal as an output signal.

10. The amplifier circuit according to claim 9, further comprising
a direct-current path that connects an output node of the first amplifier to an output node of the control amplifier in a direct-current manner via the combiner, wherein
the direct-current path is provided with a fourth node at one location to supply a bias voltage to the first amplifier and the control amplifier.

11. The amplifier circuit according to claim 5, further comprising:
another divider that divides a high frequency signal into the input signal and a fifth signal; and
a control amplifier that amplifies the fifth signal and outputs an amplified fifth signal as a sixth signal, wherein
the combiner that modulates a load of the first amplifier and the second amplifier by using the sixth signal, combines the third signal, the fourth signal, and the sixth signal into a combined signal, and outputs the combined signal as an output signal.

12. The amplifier circuit according to claim 11, further comprising
a direct-current path that connects an output node of the first amplifier to an output node of the control amplifier in a direct-current manner via the combiner, wherein
the direct-current path is provided with a fourth node at one location to supply a bias voltage to the first amplifier and the control amplifier.

13. The amplifier circuit according to claim 6, further comprising:
another divider that divides a high frequency signal into the input signal and a fifth signal; and
a control amplifier that amplifies the fifth signal and outputs an amplified fifth signal as a sixth signal, wherein
the combiner that modulates a load of the first amplifier and the second amplifier by using the sixth signal, combines the third signal, the fourth signal, and the sixth signal into a combined signal, and outputs the combined signal as an output signal.

14. The amplifier circuit according to claim 13, further comprising
a direct-current path that connects an output node of the first amplifier to an output node of the control amplifier in a direct-current manner via the combiner, wherein
the direct-current path is provided with a fourth node at one location to supply a bias voltage to the first amplifier and the control amplifier.
